(19) United States
(12) Patent Application Publication
(10) Pub. No.: US 2009/0079462 A1
(43) Pub. Date: Mar. 26, 2009

(54) Semiconductor device testing apparatus

(75) Inventor: Tu Chen Lee, Hsinchu (TW)

Correspondence Address: CHARLES E. BAXLEY, ESQUIRE, 90 JOHN STREET, SUITE 309, NEW YORK, NY, 10038, US

(73) Assignee: Zen Voce Corporation

(21) Appl. No.: 11/903,887

(22) Filed: Sep. 25, 2007

(51) Int. Cl. G01R 31/26

(52) U.S. Cl. 324/765

(57) ABSTRACT

A semiconductor device testing apparatus includes a test head Hifix, a tester coupled to the test head Hifix, two or more device-under-tests (DUTs), and one or more processor devices disposed on the test head Hifix and coupled to the DUTs for transmitting and receiving test signals between the tester and the DUTs and for receiving and processing a number of test signals from the DUTs into a single output signal and for transmitting the output signal to the tester for testing purposes. The tester may generate and transmit test signals to the test head Hifix and the DUTs for testing the DUTs to ensure that the DUTs function properly in the consumer domain.

### BACKGROUND OF THE INVENTION

1. Field of the Invention

The present invention relates to a semiconductor device testing apparatus, and more particularly to a semiconductor device testing apparatus including a processing device disposed on a test head Hifix and coupled to one or more integrated circuits to be tested or device-under-test or DUT for increasing or promoting the testing effect.

2. Description of the Prior Art

Typical semiconductor device testing apparatuses comprise a test head Hifix coupled to a single semiconductor device or integrated circuit to be tested or device-under-test (DUT) for testing the integrated circuit to ensure that the integrated circuit function properly in the consumer domain.

For example, U.S. Pat. No. 6,710,590 to Markert et al. discloses one of the typical test head Hifix devices for a semiconductor device testing apparatus including a number of printed circuit boards or pin cards coupled to a DUT with contact pins or pogo pins, and a locking mechanism disposed on top of a test head for mounting or supporting the DUT. The DUT may generate a plurality of test signals which are transmitted to the test head Hifix devices for testing purposes.

However, the typical test head Hifix for the semiconductor device testing apparatus may only be used to test a single semiconductor device or integrated circuit at one time such that the testing effect or efficiency of the semiconductor device testing apparatus is low and may not fulfill the requirements for the users or testers.

The present invention has arisen to mitigate and/or obviate the afore-described disadvantages of the conventional semiconductor device testing apparatuses.

### SUMMARY OF THE INVENTION

The primary objective of the present invention is to provide a semiconductor device testing apparatus including a processing device disposed on a test head Hifix and coupled to one or more integrated circuits to be tested or device-under-test or DUT for increasing or promoting the testing effect.

In accordance with one aspect of the invention, there is provided a semiconductor device testing apparatus comprising a test head Hifix, a tester coupled to the test head Hifix, two or more device-under-tests (DUTs), and at least one processor device disposed on the test head Hifix and coupled to the device-under-test for transmitting and receiving test signals between the tester and the device-under-test and for receiving and processing a plurality of test signals from the device-under-test into a single output signal and for transmitting the output signal to the tester for testing purposes.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a side plan schematic view of a semiconductor device testing apparatus in accordance with the present invention;

FIG. 2 is a top plan schematic view of the semiconductor device testing apparatus; and

FIG. 3 is a partial exploded view of the semiconductor device testing apparatus illustrating the operation of the semiconductor device testing apparatus.

### DETAILED DESCRIPTION OF THE PREFERRED EMBODIMENT

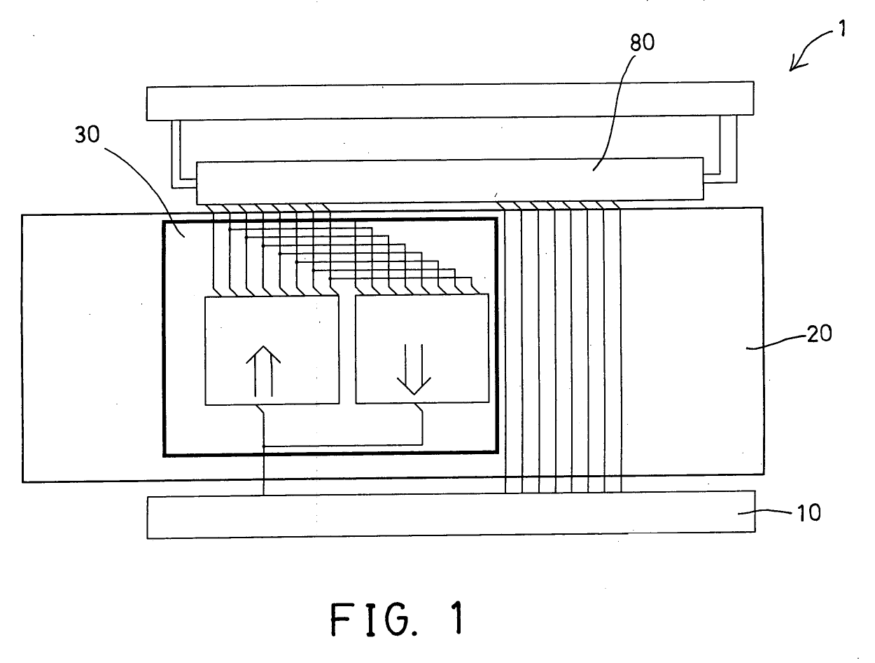

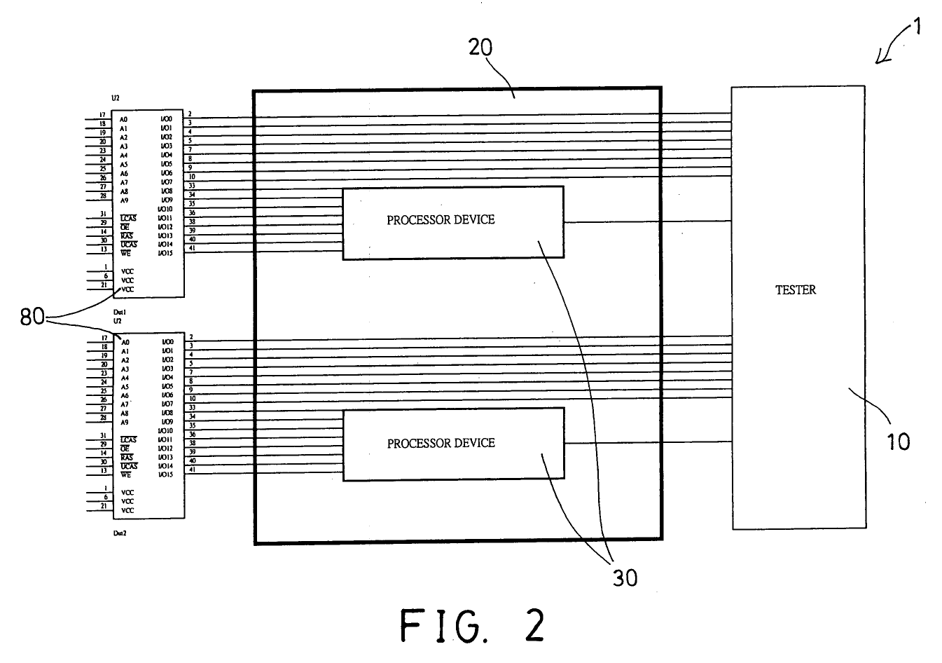

Referring to the drawings, and initially to FIGS. 1 and 2, a semiconductor device testing apparatus 1 in accordance with the present invention comprises a tester 10, and a test head or test head Hifix 20 for supporting one or more integrated circuits or semiconductor devices 80 to be tested or device-under-test or DUTs 80 and coupled to the DUTs 80, and the tester 10 may generate test signals which are transmitted to the test head Hifix 20 and then to the DUTs 80 for testing the integrated circuits or semiconductor devices or DUTs 80 to ensure that the DUTs 80 function properly in the consumer domain.

The semiconductor device testing apparatus 1 further includes one or more processor devices 30 disposed on or coupled to the test head Hifix 20 and coupled to the DUTs 80 for transmitting and/or receiving signals from or between the tester 10 and the DUTs 80. It is to be noted that the DUTs 80 may generate a plurality of test signals which are transmitted to the test head Hifix 20 and/or to the processor devices 30 and then to the tester 10. The processor devices 30 may be provided for receiving the plurality of test signals from the DUTs 80 and for converting or processing the plurality of test signals into a single output signal which is then transmitted to the tester 10.

The processor devices 30 may thus process and convert the plurality of test signals into a single output signal and may then transmit the simplified or single output signal to the tester 10 for allowing the testing speed to be greatly increased or for allowing the testing effect or efficiency of the semiconductor device testing apparatus 1 to be greatly facilitated or promoted in order to fulfill the requirements for the users or testers.

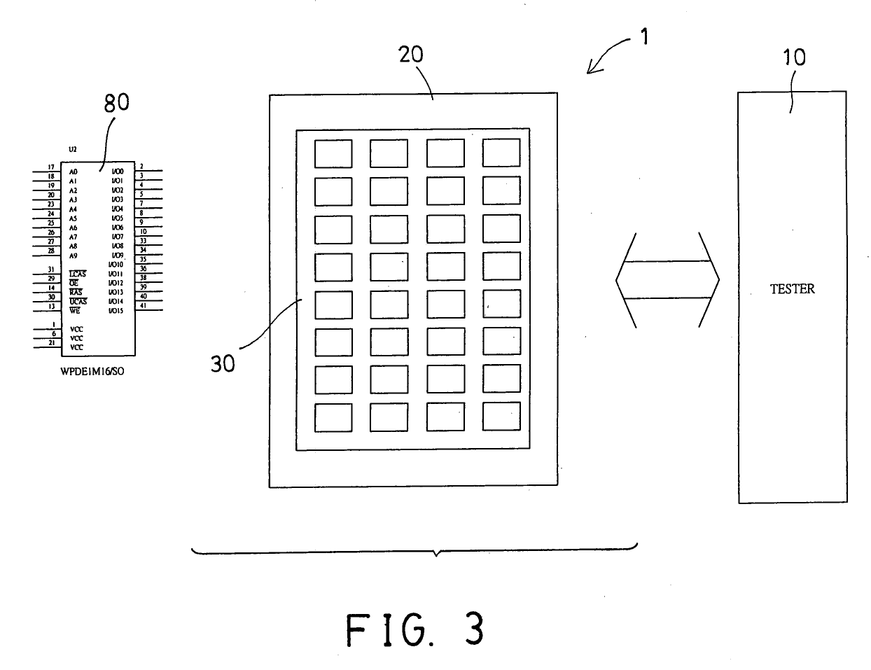

In operation, as shown in FIG. 3, one or more DUTs 80 may be coupled to the test head Hifix 20 and/or coupled to the processor devices 30 simultaneously for allowing the plurality of test signals from the DUTs 80 to be processed and converted into a single output signal and the simplified or single output signal may then be transmitted to the tester 10 for allowing the testing speed to be greatly increased or for allowing the testing effect or efficiency of the semiconductor device testing apparatus 1 to be greatly facilitated or promoted.

Accordingly, the semiconductor device testing apparatus in accordance with the present invention includes a processing device disposed on a test head Hifix and coupled to one or more integrated circuits to be tested or device-under-test or DUT for increasing or promoting the testing effect.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A semiconductor device testing apparatus comprising:
a test head Hifix,
a tester coupled to said test head Hifix,
at least two device-under-test, and
at least one processor device disposed on said test head Hifix and coupled to said at least two device-under-test for transmitting and receiving test signals between said tester and said at least two device-under-test and for receiving and processing a plurality of test signals from said at least two device-under-test into a single output signal and for transmitting the output signal to said tester for testing purposes.
